(19) United States
(12) Patent Application Publication
(10) Pub. No.: US 2026/0231485 A1
(43) Pub. Date: Aug. 6, 2026

(54) SEMICONDUCTOR DEVICE AND POWER CONVERSION DEVICE

(71) Applicant: Mitsubishi Electric Corporation, Chiyoda-ku, Tokyo (JP)

(72) Inventors: Kazunari NAKATA, Tokyo (JP); Keiji BEPPU, Tokyo (JP); Munenori IKEDA, Tokyo (JP)

(73) Assignee: Mitsubishi Electric Corporation, Chiyoda-ku, Tokyo (JP)

(21) Appl. No.: 19/152,745

(22) PCT Filed: Mar. 19, 2024
(86) PCT No.: PCT/JP2024/010727

§ 371 Date: Jul. 31, 2025

(30) Foreign Application Priority Data
Apr. 12, 2023 (JP) 2023-064654

(51) Int. Cl. H10D 62/10; H02M 7/00; H10D 30/66

(52) U.S. Cl. CPC H10D 62/115; H10D 30/66; H02M 7/003

(57) ABSTRACT

An object is to provide a technology that can enhance the reliability of a semiconductor device. The semiconductor device includes: a first electrode provided on a first insulating film; a second insulating film covering a reference plane of a semiconductor substrate, the first insulating film, and the first electrode; and a second electrode covering the reference plane and the second insulating film, wherein a side surface of the second insulating film includes a plurality of partial side surfaces forming different angles with the reference plane, and a second angle formed between the reference plane and a partial side surface corresponding in height to a first side surface of the first electrode is smaller than a first angle formed between the first side surface and the reference plane, the partial side surface being included in the plurality of partial side surfaces.

### BACKGROUND OF THE INVENTION

### Field of the Invention

The present disclosure relates to a semiconductor device and a power conversion device.

### Description of the Background Art

Semiconductor devices have found applications in power semiconductor devices made of silicon carbide (SiC) superior in breakdown voltage, low resistance, and heat resistance to silicon (Si) so that, for example, the semiconductor devices can increase the breakdown voltage, reduce losses, and be used under high-temperature environments. Known power semiconductor devices include a metal-oxide semiconductor field-effect transistor (MOSFET) and an insulated-gate bipolar transistor (IGBT). For example, a MOSFET made of SiC at 1 to 1.2 kV breakdown voltage level can have a ON resistance of 2 mΩcm² or lower, and can have a resistance value less than or equal to half a resistance value of a MOSFET and an IGBT made of Si with the same breakdown voltage. Conceivable reasons why ON resistances of SiC semiconductor devices can be reduced more significantly than those of Si semiconductor devices are that the SiC semiconductor devices have higher dielectric breakdown field, can make breakdown voltage layers (i.e., drift layers) for implementing the breakdown voltages thinner than those of Si semiconductor devices, and increase the impurity doping amounts of the breakdown voltage layers.

Semiconductor devices can be downsized by increasing a current density at which a current is passed through a semiconductor device, and the manufacturing cost of the semiconductor devices can be reduced by using parasitic diodes in MOSFET. In view of these, semiconductor devices made of SiC will become the mainstream of inverter components from now on.

Continuously passing a forward current, specifically, a bipolar current through a SiC p-n diode, however, increases recombined energy obtained when minority carriers injected in passing the current through the p-n diode are recombined with majority carriers. This consequently expands stacking faults that are plane defects, starting from, for example, basal plane dislocations in a SiC substrate. Since expansion of stacking faults reduces the current and increases the forward current, that is, shifts the forward current, the performance of the semiconductor device decreases, and even the reliability decreases.

Various technologies have been proposed to suppress the decrease in reliability in passing the forward current through the parasitic p-n diode as described above. For example, Patent Document 1 proposes providing a p⁺ type semiconductor region that is a hole-extracting region to surround an active region including MOSFETs, in a semiconductor substrate including an n-type SiC substrate and an epitaxial growth layer on the SiC substrate. Furthermore, Patent Documents 2 and 3 propose embedding a Schottky barrier diode (SBD) as a unipolar diode in a semiconductor chip corresponding to a MOSFET.

### PRIOR ART DOCUMENT

### Patent Document

[Patent Document 1] Japanese Patent Application Laid-Open No. 2019-75411
[Patent Document 2] Japanese U.S. Pat. No. 7,078,226
[Patent Document 3] Japanese U.S. Pat. No. 7,170,781

### SUMMARY

### Problem to Be Solved by the Invention

Downsizing a semiconductor device and increasing the efficiency thereof, however, increases a current density at normal times, which increases the operating temperature. When thermal stresses caused by this temperature increase are intensified, problems occur, that is, a gate electrode in a termination region is prone to deteriorate, and the reliability of the semiconductor device is impaired.

Thus, the present disclosure has been made in view of the problems, and has an object of providing a technology that can enhance the reliability of the semiconductor device.

### Means to Solve the Problem

A semiconductor device according to the present disclosure includes: a semiconductor substrate; a first insulating film provided on a reference plane of the semiconductor substrate; a first electrode provided on the first insulating film; a second insulating film covering the reference plane, the first insulating film, and the first electrode; and a second electrode covering the reference plane and the second insulating film, wherein a side surface of the second insulating film includes a plurality of partial side surfaces forming different angles with the reference plane, and a second angle formed between the reference plane and a partial side surface corresponding in height to a first side surface of the first electrode is smaller than a first angle formed between the first side surface and the reference plane, the partial side surface being included in the plurality of partial side surfaces.

### Effects of the Invention

According to the present disclosure, the second angle formed between the reference plane and the partial side surface corresponding in height to the first side surface of the first electrode is smaller than the first angle formed between the first side surface and the reference plane, the partial side surface being included in the plurality of partial side surfaces. With such a structure, the reliability of the semiconductor device can be enhanced.

The object, features, aspects, and advantages of the present disclosure will become more apparent from the following detailed description and the accompanying drawings.

### BRIEF DESCRIPTION OF THE DRAWINGS

FIG. 1 is a top view illustrating a structure of a semiconductor device according to Embodiment 1.

FIG. 2 is a top view illustrating the structure of the semiconductor device according to Embodiment 1.

FIG. 3 is a cross-sectional schematic diagram illustrating the structure of the semiconductor device according to Embodiment 1.

FIG. 4 is a flowchart illustrating a method of manufacturing the semiconductor device according to Embodiment 1.

FIG. 5 is a cross-sectional schematic diagram illustrating a step for manufacturing the semiconductor device according to Embodiment 1.

FIG. 6 is a cross-sectional schematic diagram illustrating a step for manufacturing the semiconductor device according to Embodiment 1.

FIG. 7 is a cross-sectional schematic diagram illustrating a step for manufacturing the semiconductor device according to Embodiment 1.

FIG. 8 is a cross-sectional schematic diagram illustrating a step for manufacturing the semiconductor device according to Embodiment 1.

FIG. 9 is a cross-sectional schematic diagram illustrating a step for manufacturing the semiconductor device according to Embodiment 1.

FIG. 10 is a cross-sectional schematic diagram illustrating a step for manufacturing the semiconductor device according to Embodiment 1.

FIG. 11 is a cross-sectional schematic diagram illustrating a step for manufacturing the semiconductor device according to Embodiment 1.

FIG. 12 is a cross-sectional schematic diagram illustrating a step for manufacturing the semiconductor device according to Embodiment 1.

FIG. 13 is a cross-sectional schematic diagram illustrating a step for manufacturing the semiconductor device according to Embodiment 1.

FIG. 14 is a cross-sectional schematic diagram illustrating a step for manufacturing the semiconductor device according to Embodiment 1.

FIG. 15 is a cross-sectional schematic diagram illustrating a step for manufacturing the semiconductor device according to Embodiment 1.

FIG. 16 is a cross-sectional schematic diagram illustrating a step for manufacturing the semiconductor device according to Embodiment 1.

FIG. 17 is a cross-sectional schematic diagram illustrating a step for manufacturing the semiconductor device according to Embodiment 1.

FIG. 18 is a cross-sectional schematic diagram illustrating a structure of a semiconductor module according to Embodiment 1.

FIG. 19 is a cross-sectional schematic diagram and a SEM photograph which illustrate the structure of the semiconductor device according to Embodiment 1.

FIG. 20 is a diagram illustrating a test result of the semiconductor device according to Embodiment 1.

FIG. 21 is a diagram illustrating a test result of the semiconductor device according to Embodiment 1.

FIG. 22 is a cross-sectional schematic diagram illustrating a structure of a semiconductor device according to a modification of Embodiment 1.

FIG. 23 is a cross-sectional schematic diagram illustrating a structure of a semiconductor device according to Embodiment 2.

FIG. 24 is a cross-sectional schematic diagram illustrating a step for manufacturing the semiconductor device according to Embodiment 2.

FIG. 25 is a cross-sectional schematic diagram illustrating a step for manufacturing the semiconductor device according to Embodiment 2.

FIG. 26 is a cross-sectional schematic diagram illustrating a step for manufacturing the semiconductor device according to Embodiment 2.

FIG. 27 is a cross-sectional schematic diagram illustrating a structure of a semiconductor device according to a modification of Embodiment 2.

FIG. 28 is a cross-sectional schematic diagram illustrating a structure of a semiconductor device according to Embodiment 3.

FIG. 29 is a top view illustrating a structure of a semiconductor device according to Embodiment 4.

FIG. 30 is a cross-sectional schematic diagram illustrating the structure of the semiconductor device according to Embodiment 4.

FIG. 31 is a flowchart illustrating a method of manufacturing the semiconductor device according to Embodiment 4.

FIG. 32 is a cross-sectional schematic diagram illustrating a step for manufacturing the semiconductor device according to Embodiment 4.

FIG. 33 is a cross-sectional schematic diagram illustrating a step for manufacturing the semiconductor device according to Embodiment 4.

FIG. 34 is a cross-sectional schematic diagram illustrating the structure of the semiconductor device according to Embodiment 4.

FIG. 35 is a block diagram illustrating a configuration of a power conversion system to which a power conversion device according to Embodiment 5 is applied.

### DESCRIPTION OF THE PREFERRED EMBODIMENTS

Embodiments will be described with reference to the attached drawings. The features to be described in Embodiments below are exemplifications, and all of the features are not necessarily essential. In the description below, identical constituent elements in a plurality of Embodiments will be denoted by the same or similar reference numerals, and different constituent elements will be mainly described. In the following description, a particular position and a particular direction such as “up” or “down” need not always coincide with an actual position and an actual direction. A portion higher in concentration than another portion means that, for example, an average of concentrations in the portion is higher than an average of concentrations in the other portion. Conversely, a portion lower in concentration than another portion means that, for example, an average of concentrations in the portion is lower than an average of concentrations in the other portion.

### Embodiment 1

An example where a semiconductor device according to Embodiment 1 is a power semiconductor device, includes an n-type SiC substrate, and is a planar-gate metal-oxide semiconductor field-effect transistor (MOSFET) embedding a Schottky barrier diode (SBD) will be described. The semiconductor device is not limited to this but may be, for example, a trench-gate semiconductor device, an insulated-gate bipolar transistor (IGBT), or a reverse-conducting IGBT (RC-IGBT).

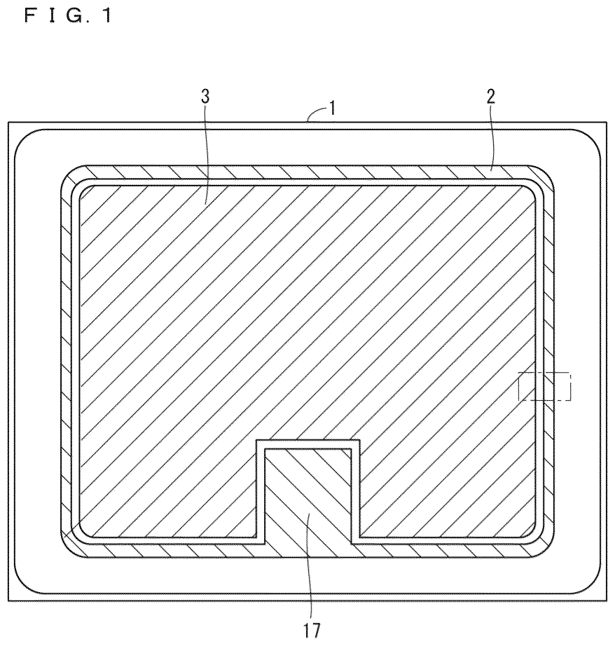

FIG. 1 is a top view illustrating a structure of a semiconductor device 1 according to Embodiment 1. On the top of the semiconductor device 1, a source electrode 3 located in a center portion, and a gate wire 2 surrounding the source electrode 3 are provided. Furthermore, a gate pad 17 is provided between the center and the end of the upper portion of the semiconductor device 1 to be electrically connected to the gate wire 2. The gate wire 2 and the gate pad 17 are spaced and insulated from the source electrode 3. In this Description, a region in which unit cells are periodically arranged is defined as an active region, and a region other than the active region is defined as a termination region.

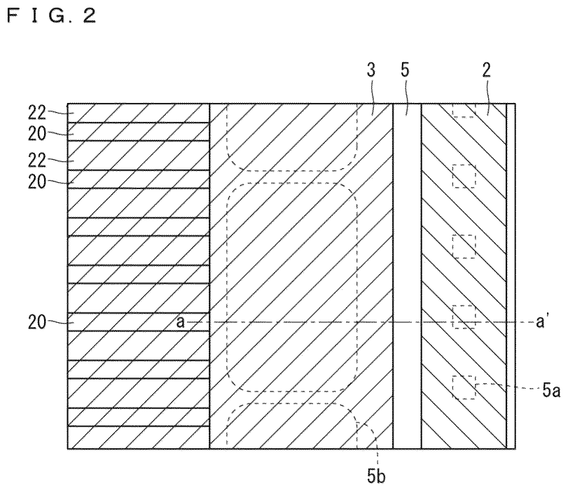

FIG. 2 is a top view illustrating an enlarged view of a portion between the active region and the termination region which is indicated by an alternate long and short dashed line in FIG. 1. In Embodiment 1, the active region includes SBD regions 20 provided with an SBD, and MOS regions 22 provided with a MOSFET, and the SBD regions 20 and the MOS regions 22 are arranged in stripes.

A second interlayer insulating film 5 is disposed in a region other than the active region including the SBD regions 20 and the MOS regions 22, that is, in the termination region. The gate wire 2 and the source electrode 3 are disposed on the second interlayer insulating film 5. The second interlayer insulating film 5 has gate contact holes 5a covered with the gate wire 2, and contact holes 5b covered with the source electrode 3. As will be described later, an SBD is provided below the contact holes 5b in the termination region, similarly to the SBD regions 20 in the active region.

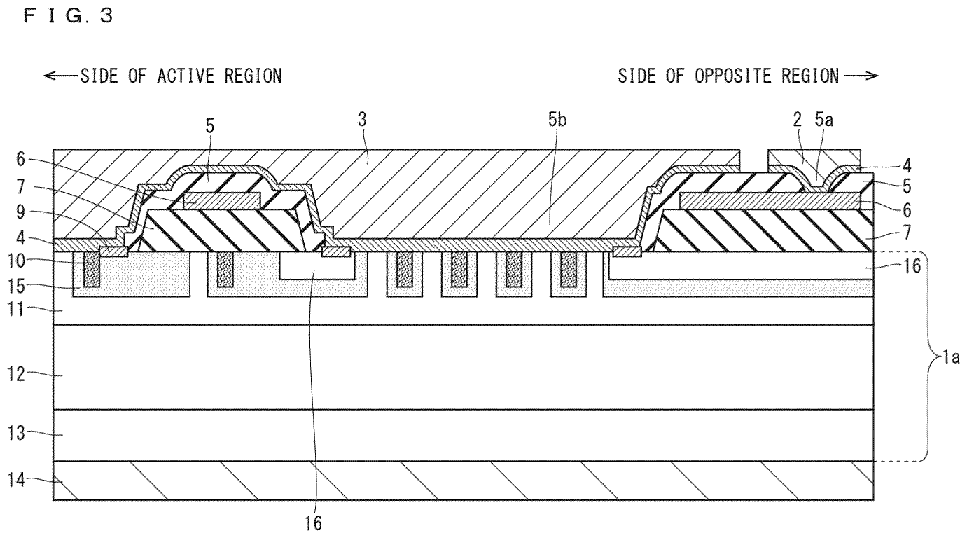

FIG. 3 is a cross-sectional schematic diagram illustrating a structure of a portion taken along an a-a′ line in FIG. 2. Since the second interlayer insulating film 5 is disposed in the termination region as described above, FIG. 3 mostly illustrates the structure of the termination region. Since the a-a′ line in FIG. 2 extends across the contact hole 5b of the second interlayer insulating film 5, FIG. 3 illustrates the second interlayer insulating film 5 in two portions that sandwich the contact hole 5b.

As illustrated in FIG. 3, the semiconductor device 1 according to Embodiment 1 includes, in the termination region, an n-type SiC substrate 13, an n-type epitaxial growth layer 12, an n-type well region 11, a p-type well region 15, p-type potential fixed layers 10, n-type source regions 16, contact regions 9, a first interlayer insulating film 7, a gate electrode 6, the second interlayer insulating film 5, a barrier metal layer 4, the source electrode 3, the gate wire 2, and a drain electrode 14. In Embodiment 1, a semiconductor substrate 1a includes the SiC substrate 13 and the epitaxial growth layer 12. The semiconductor substrate 1a is not limited to this but may include, for example, not the SiC substrate 13 but the epitaxial growth layer 12, or not the epitaxial growth layer 12 but the SiC substrate 13.

The epitaxial growth layer 12 is uniformly provided on a first main surface (an upper surface in FIG. 3) of the SiC substrate 13, and the n-type well region 11 is provided on the epitaxial growth layer 12. The p-type well region 15 is selectively provided on the top of the n-type well region 11. A side portion and a lower portion of each of the p-type potential fixed layers 10 are covered with the p-type well region 15, and a side portion and a lower portion of each of the source regions 16 are covered with the p-type well region 15.

The first interlayer insulating film 7 that is a first insulating film is provided on a reference plane of the semiconductor substrate 1a. In an example of FIG. 3, the reference plane is a top surface, and the first interlayer insulating film 7 is selectively provided on the potential fixed layers 10, the n-type well region 11, the p-type well region 15, and the source regions 16 in the termination region. Since the first interlayer insulating film 7 has the contact holes 5b similarly to the second interlayer insulating film 5, FIG. 3 illustrates the first interlayer insulating film 7 in two portions similarly to the second interlayer insulating film 5.

The gate electrode 6 that is a first electrode is provided on the first interlayer insulating film 7. In the two portions of the first interlayer insulating film 7 illustrated in FIG. 3, a region opposite to the active region with respect to the gate electrode 6 provided on the first interlayer insulating film 7 on the side of the active region will be referred to as an opposite region and described hereinafter.

The gate electrode 6 is electrically connected to a gate electrode (not illustrated) provided on the MOS regions 22 in FIG. 2, and has a potential identical to that of the gate electrode on the MOS regions 22. When a voltage higher than or equal to a threshold voltage is applied to the gate electrode on the MOS regions 22, a conductivity type of a portion of a p-type semiconductor layer sandwiched between n-type semiconductor layers is inverted, and a channel is formed in the portion. Since the structure of FIG. 3 is not directed to the MOS regions 22, the gate electrode 6 in FIG. 3 forms a channel in the p-type semiconductor layer indirectly in the MOS region, but does not form a channel directly in the p-type semiconductor layer in FIG. 3.

The second interlayer insulating film 5 that is a second insulating film is provided to cover the reference plane of the semiconductor substrate 1a, the first interlayer insulating film 7, and the gate electrode 6. The second interlayer insulating film 5 has the gate contact holes 5a partially exposing the gate electrode 6 provided on the first interlayer insulating film 7 on a side of the opposite region, and the contact holes 5b partially exposing the n-type well region 11 in the termination region.

The barrier metal layers 4 cover the p-type potential fixed layers 10, the n-type well region 11, the p-type well region 15, the source regions 16, the second interlayer insulating film 5, and the gate electrode 6 exposed from the gate contact holes 5a. The barrier metal layer 4 connected to the gate electrode 6 is spaced and insulated from the barrier metal layer 4 covering, for example, the n-type well region 11.

The contact region 9 is provided between the barrier metal layer 4 and one of the source regions 16, the p-type well region 15, and the p-type potential fixed layers 10 on the side of the active region with respect to the first interlayer insulating film 7, and ohmic-connects these.

The contact region 9 is not provided between the barrier metal layer 4 and the n-type well region 11 in the contact holes 5b. The n-type well region 11 is Schottky-connected to the barrier metal layer 4. Thus, the SBD is provided below the contact holes 5b, similarly to the SBD regions 20 in the active region in FIG. 2.

The gate wire 2 is electrically continuous to the gate electrode 6 through the barrier metal layer 4 covering the gate electrode 6 exposed from the gate contact holes 5a.

The source electrode 3 that is a second electrode covers the reference plane of the semiconductor substrate 1a and the second interlayer insulating film 5. In the example of FIG. 3, the source electrode 3 is electrically continuous to, for example, the n-type well region 11 through the barrier metal layer 4 covering, for example, the n-type well region 11. The drain electrode 14 is provided on a second main surface (a bottom surface in FIG. 3) opposite to the first main surface in which the epitaxial growth layer 12 on the SiC substrate 13 is provided.

In Embodiment 1 herein, the side surface of the second interlayer insulating film 5 includes a plurality of partial side surfaces forming different angles with the reference plane (the top surface in FIG. 3) of the semiconductor substrate 1a. Furthermore, a second angle formed between the reference plane and a partial side surface corresponding in height to a first side surface of the gate electrode 6 in the plurality of partial side surfaces is smaller than a first angle formed between the first side surface and the reference plane. Furthermore, a fourth angle formed between the reference plane and a partial side surface corresponding in height to a second side surface of the first interlayer insulating film 7 in the plurality of partial side surfaces is larger than a third angle formed between the second side surface and the reference plane. These will be described later in detail.

### Manufacturing Method

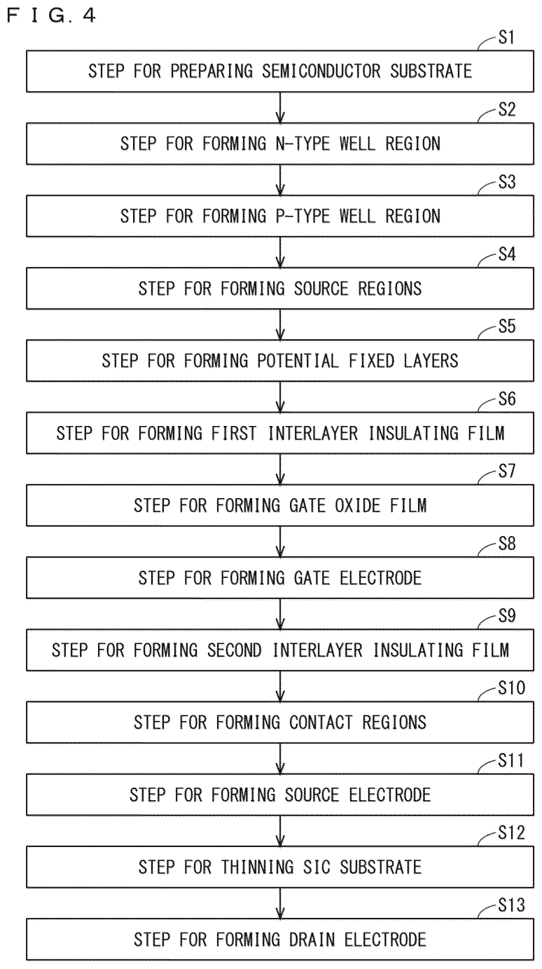

FIG. 4 is a flowchart illustrating a method of manufacturing the semiconductor device according to Embodiment 1. Hereinafter, each of Step S1 for preparing a semiconductor substrate to Step S13 for forming a drain electrode will be described.

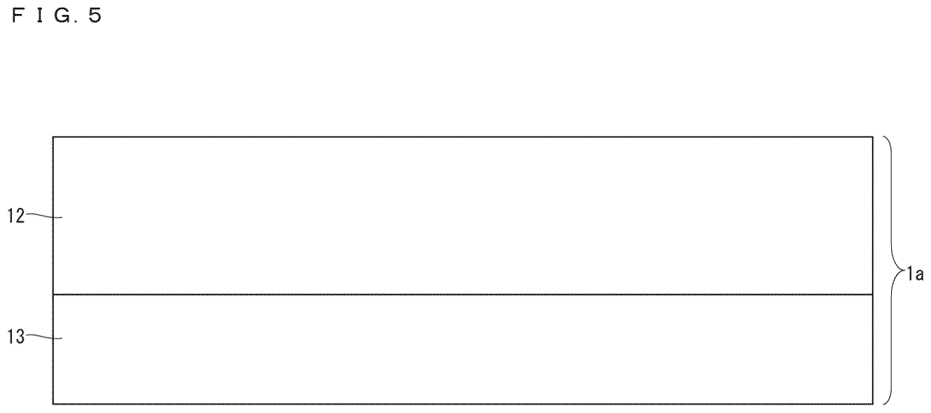

First, in Step S1 for preparing the semiconductor substrate, the epitaxial growth layer 12 made of n-type SiC is formed on the first main surface of the n-type SiC substrate 13 of a 4H polytype by chemical vapor deposition (CVD) as illustrated in FIG. 5. This forms the semiconductor substrate 1a including the SiC substrate 13 and the epitaxial growth layer 12. The n-type impurity concentration of the epitaxial growth layer 12 ranges, for example, from 1×10¹⁵ cm⁻³ to 1×10¹⁷ cm⁻³. Furthermore, the thickness of the epitaxial growth layer 12 ranges, for example, from 5 μm to 50 μm. While the SiC substrate 13 is of n-type in Embodiment 1, the SiC substrate 13 may be of p-type.

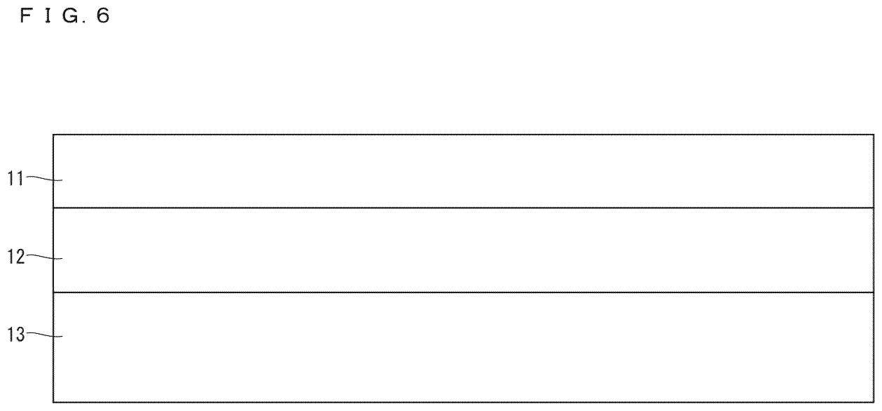

Next, in Step S2 for forming an n-type well region, impurities are ion-implanted on the top of the epitaxial growth layer 12 to form the n-type well region 11 as illustrated in FIG. 6. The impurity concentration of the n-type well region 11 is higher than that of the epitaxial growth layer 12.

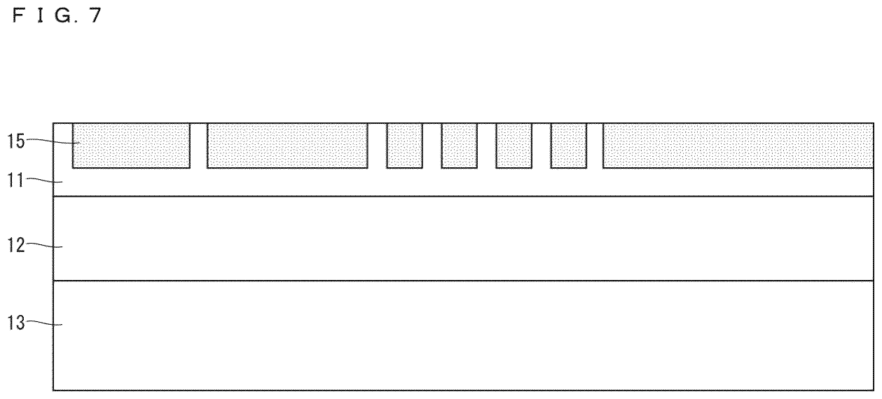

Then, in Step S3 for forming a p-type well region, an implantation mask is formed in a predefined region of the n-type well region 11 using, for example, a photoresist, and then, p-type impurities are ion-implanted to form the p-type well region 15 as illustrated in FIG. 7. Examples of the p-type impurities include boron (B) and aluminum (Al). A depth of implantation into the p-type well region 15 is less than a depth of the n-type well region 11. Furthermore, the impurity concentration of the p-type well region 15 ranges, for example, from 1×10¹⁷ cm⁻³ to 1×10¹⁹ cm⁻³.

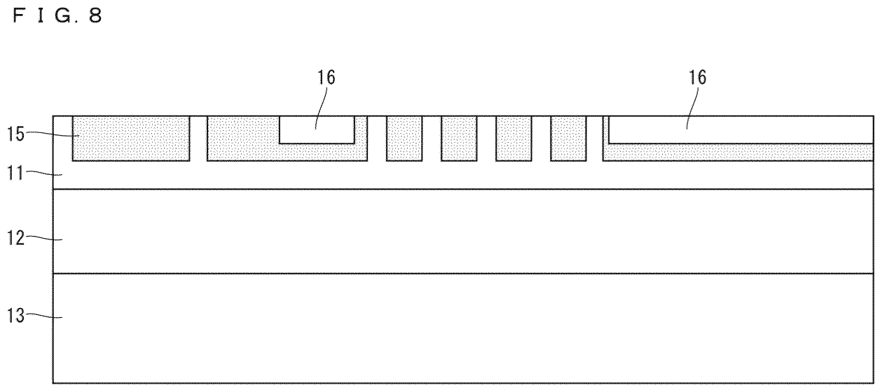

Then, in Step S4 for forming source regions, an implantation mask is formed in a predefined region of the p-type well region 15 using, for example, a photoresist, and then, n-type impurities are ion-implanted to form the source regions 16 as illustrated in FIG. 8. Examples of the n-type impurities include phosphorus and nitrogen. A depth of implantation into the source regions 16 is less than a depth of the p-type well region 15.

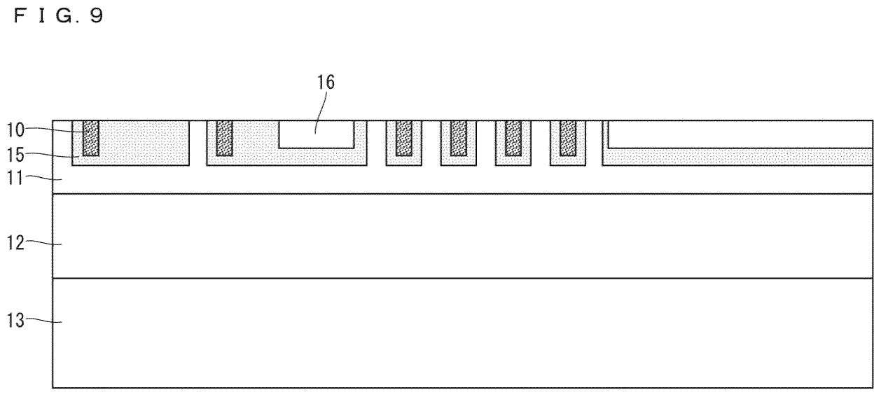

Then, in Step S5 for forming potential fixed layers, an implantation mask is formed in a predefined region of the p-type well region 15 using, for example, a photoresist, and then, p-type impurities are ion-implanted to form the potential fixed layers 10 as illustrated in FIG. 9. The impurity concentration of the potential fixed layers 10 is higher than that of the p-type well region 15. Next, a heat treatment apparatus anneals a structure obtained in the step illustrated in FIG. 9 at a temperature ranging from 1300 to 1900° C. in an inert gas atmosphere such as argon (Ar) gas for 30 seconds to 1 hour. This annealing electrically activates the implanted p-type and n-type impurities.

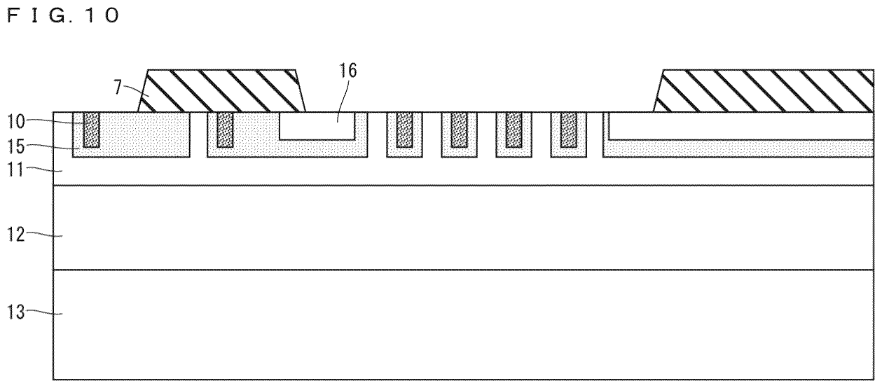

Then, in Step S6 for forming the first interlayer insulating film, an insulating film to be the first interlayer insulating film 7 is formed by CVD, and then, the insulating film is patterned using a photolithography technique and a dry or wet etching technique. This forms the first interlayer insulating film 7 remaining in a predefined region on the potential fixed layers 10, the n-type well region 11, the p-type well region 15, and the source regions 16 as illustrated in FIG. 10. Example materials of the first interlayer insulating film 7 include tetra ethoxy silane (TEOS).

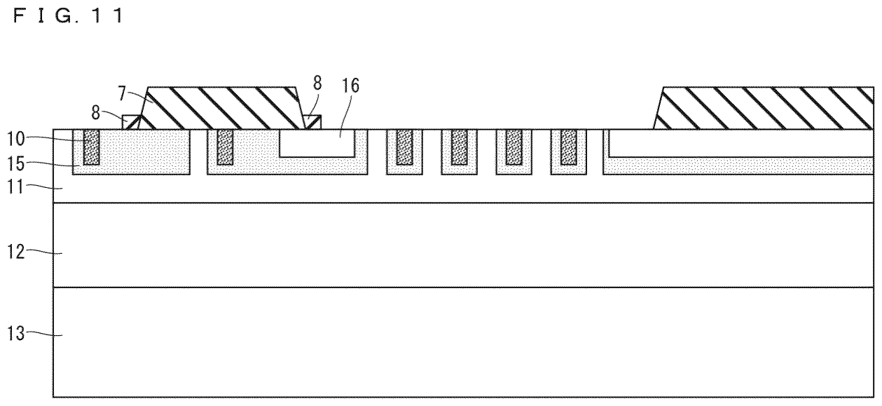

Next, in Step S7 for forming a gate oxide film, a gate oxide film is formed in the active region and the termination region. Although not illustrated, the gate oxide film in the active region insulates, from a semiconductor layer of each of n-type and p-type, a gate electrode forming a channel in the active region. While a gate oxide film 8 is formed also in the termination region in Embodiment 1 as illustrated in FIG. 11, the gate oxide film 8 is not limited to this but need not be provided in the termination region.

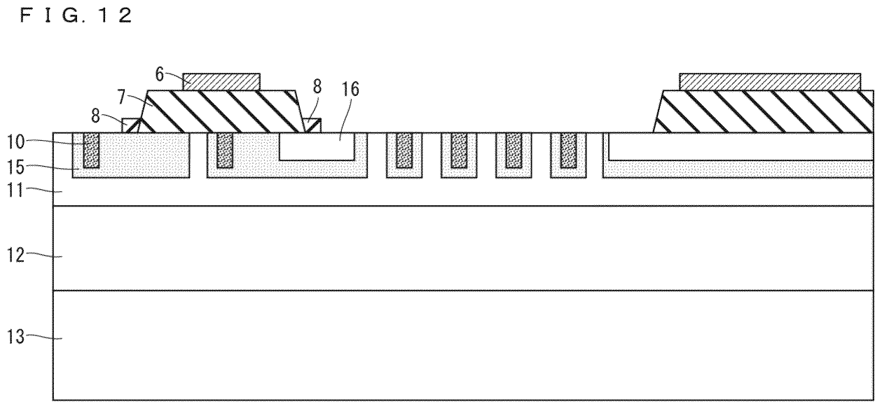

Next, in Step S8 for forming a gate electrode, a conductive film is deposited on, for example, the gate oxide film in the active region and the first interlayer insulating film 7 in the termination region by thermal oxidation or CVD. Then, the conductive film is patterned using the photolithography technique and the dry or wet etching technique. This forms the gate electrode 6 on an upper surface of the gate oxide film in the active region, and on an upper surface of the first interlayer insulating film 7 in the termination region as illustrated in FIG. 12. Example materials of the conductive film to be the gate electrode 6 may include polycrystalline Si or poly-Si to be deposited using chemical vapor deposition, etc., and tungsten or tungsten silicide (WSiₓ) when the semiconductor device 1 performs operations at higher speeds.

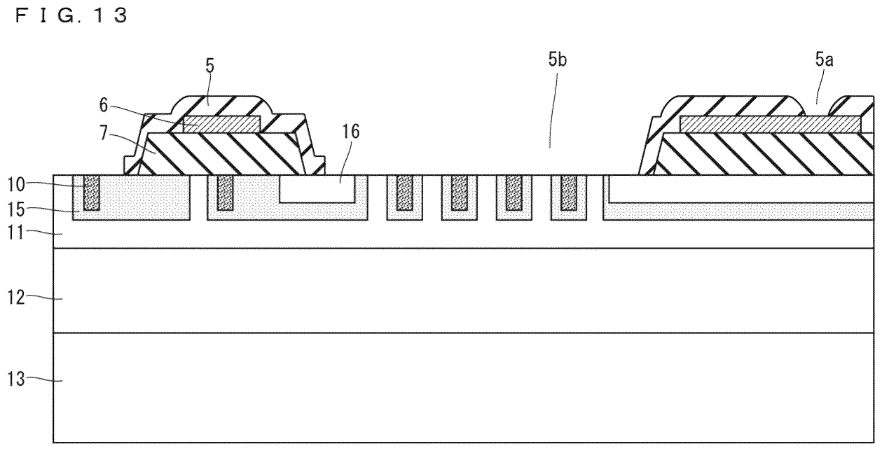

Then, in Step S9 for forming the second interlayer insulating film, an insulating film to be the second interlayer insulating film 5 is formed by CVD, and then, the insulating film is patterned using the photolithography technique and the dry or wet etching technique. This forms the second interlayer insulating film 5 that covers the gate electrode 6 and the first interlayer insulating film 7 and has the gate contact hole 5a and the contact hole 5b as illustrated in FIG. 13. The gate oxide film 8 is a part of the second interlayer insulating film 5 in Embodiment 1. Example materials of the second interlayer insulating film 5 include tetra ethoxy silane (TEOS) and borophosphosilicate glass (BPSG).

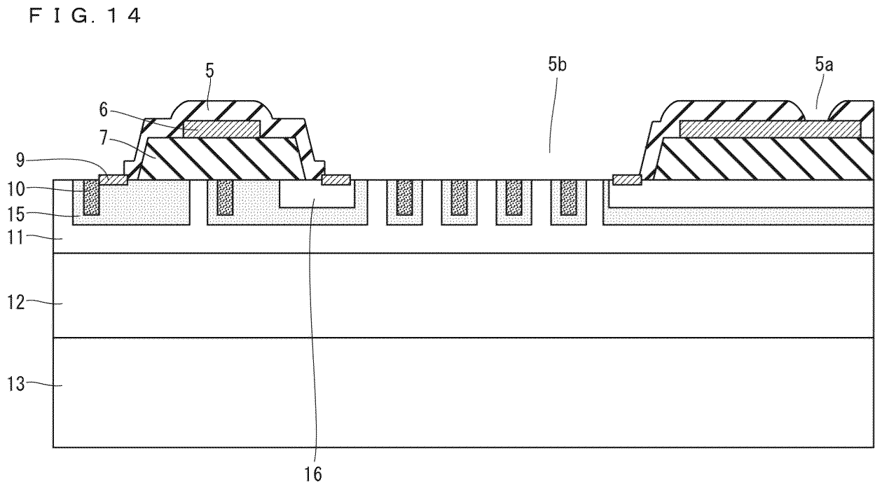

Next, in Step S10 for forming contact regions, the contact regions 9 are formed as illustrated in FIG. 14. Each of the contact regions 9 is, for example, a nickel silicide layer formed by depositing a metal film containing nickel (Ni) as a main component, on an opening in, for example, the photoresist by sputtering and subjecting the metal film to a thermal process at a temperature ranging from 600 to 1100° C.

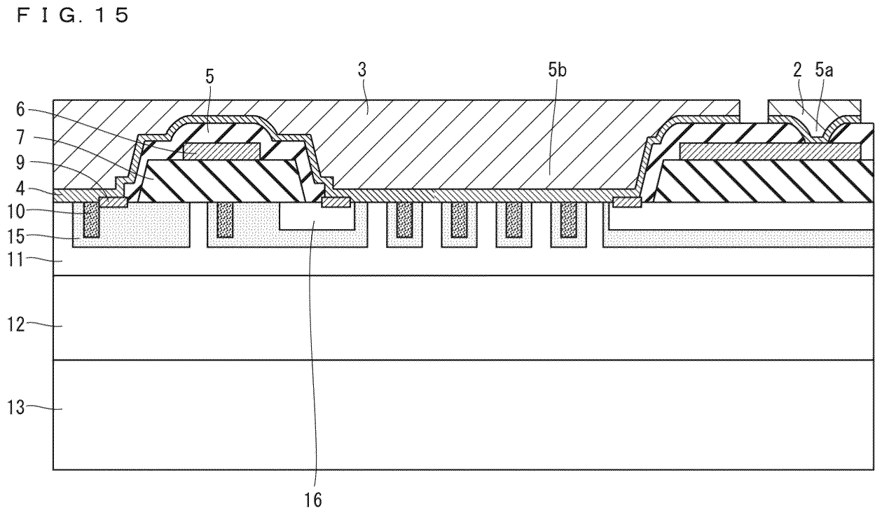

Next, in Step S11 for forming a source electrode, the barrier metal layer 4 made of titanium or a titanium compound such as or titanium nitride (TiN) is formed as illustrated in FIG. 15. Then, depositing, for example, one of aluminum and an aluminum alloy of aluminum and silicon, or nickel forms the gate wire 2 and the source electrode 3.

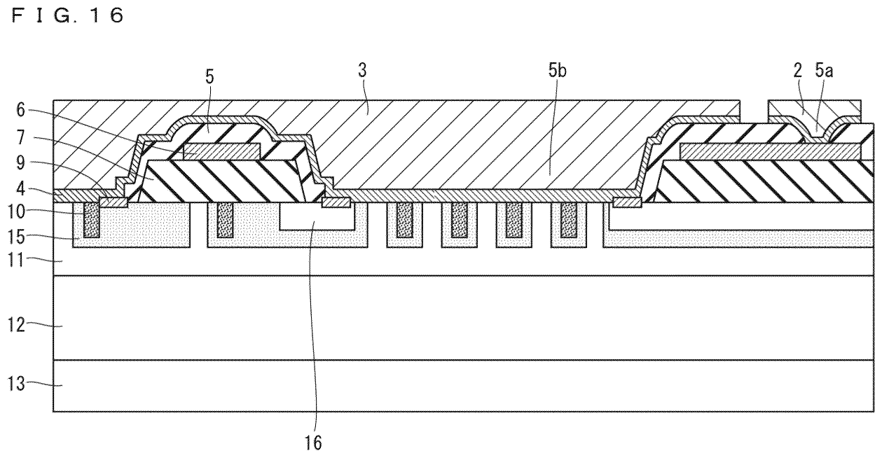

Then, in Step S12 for thinning an SiC substrate, machining the second main surface of the SiC substrate 13 using a grinding wheel makes the SiC substrate 13 leaner as illustrated in FIG. 16.

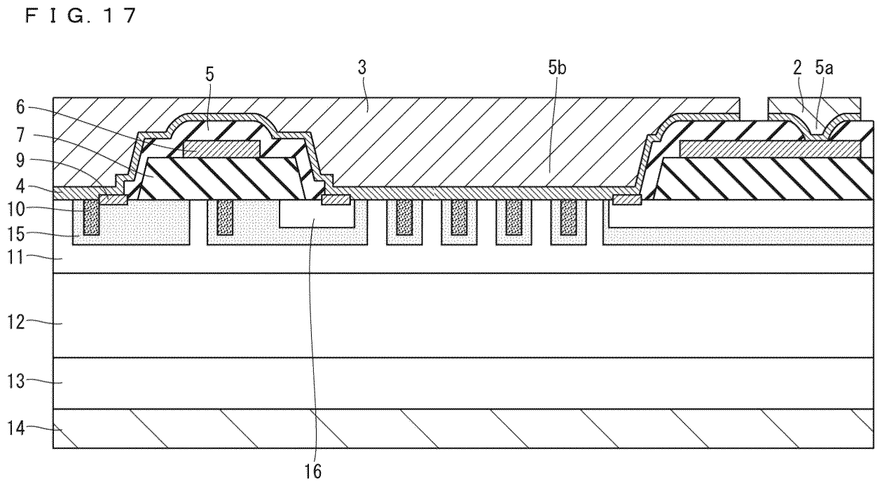

Next, in Step S13 for forming a drain electrode, depositing, for example, a nickel film of approximately 600 nm on the machined second main surface appropriately using sputtering, etc., forms the drain electrode 14 as illustrated in FIG. 17. When the front most surface of the nickel film is oxidized, the wettability of a solder alloy on the nickel film is worsened, and a bonding state in bonding chips is worsened. Thus, a film containing a metal that is less reactive to an outside such as gold (Au) and silver (Ag) may be formed on the front surface of the nickel film as a protective film. In other words, the drain electrode 14 may be a laminated film of the nickel film and the protective film.

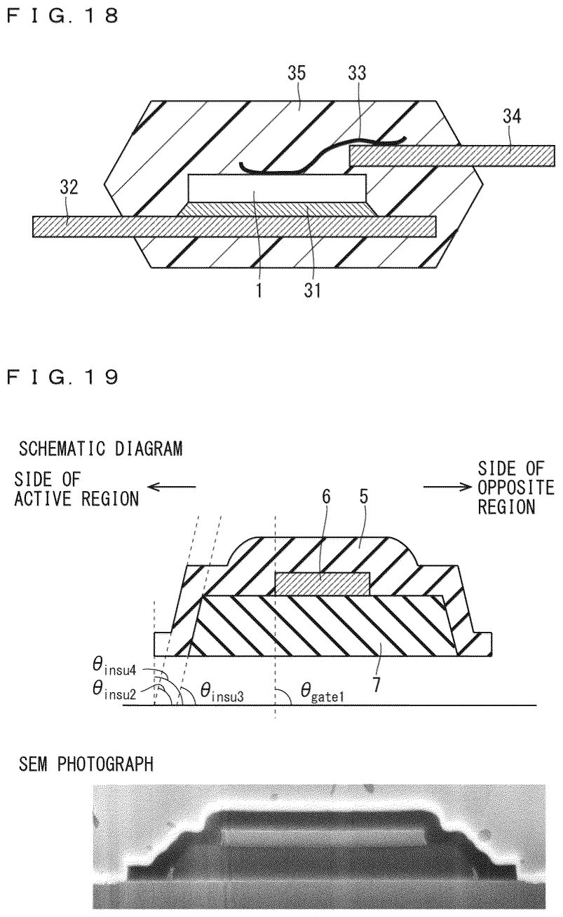

Then, a back surface (i.e., the second main surface) of the semiconductor device 1 is connected to a lead frame 32 through solder 31, and a front surface (i.e., the first main surface) of the semiconductor device 1 is connected to a lead frame 34 through a wire 33 as illustrated in FIG. 18. Then, sealing, for example, the semiconductor device 1 and the wire 33 by a mold resin 35 completes a semiconductor module including the semiconductor device 1.

### Summary of Embodiment 1

In an inverter circuit including a power semiconductor device, a diode referred to as a freewheeling diode or a flywheel diode is anti-parallel connected to an inductive load to suppress an increase in source-drain voltage.

In such an inverter circuit, a current flows through the aforementioned diode in a freewheeling operation. The semiconductor device 1 including, in the termination region, a body diode (BD) region and a Schottky barrier diode (SBD) region for allowing a current to flow in a freewheeling operation generates heat in the termination region of the semiconductor device 1.

Thermal stresses caused by differences in thermal expansion coefficient between various materials such as the gate electrode 6, the second interlayer insulating film 5 covering the gate electrode 6, and the source electrode 3 and the mold resin 35 which surround the second interlayer insulating film 5 occur in the gate electrode 6 and the second interlayer insulating film 5 covering the gate electrode 6 due to a temperature difference between a heat generation time and a non-heat generation time in the termination region. These thermal stresses add external forces to the gate electrode 6 through the second interlayer insulating film 5, so that the gate electrode 6 deteriorates and the semiconductor device 1 malfunctions. The semiconductor device 1 according to Embodiment 1 can suppress the malfunction as will be described below.

FIG. 19 illustrates a schematic diagram of a structure of the termination region in the semiconductor device 1 according to Embodiment 1, and a SEM photograph of an image of the structure which has been captured by a scanning electron microscope (SEM). The schematic diagram indicates θ_{gate1} as a first angle, θᵢₙₛᵤ₂ as a second angle, θᵢₙₛᵤ₃ as a third angle, and θᵢₙₛᵤ₄ as a fourth angle.

θ_{gate1} denotes an angle formed on the same side as the gate electrode 6 between a first side surface of the gate electrode 6 and the reference plane of the semiconductor substrate 1a. In Embodiment 1, θ_{gate1} denotes an angle formed between a tangential line of a midpoint portion of the first side surface of the gate electrode 6 in a thickness direction (a vertical direction in the schematic diagram) of the gate electrode 6, and the reference plane of the semiconductor substrate 1a.

θᵢₙₛᵤ₂ denotes an angle formed on the same side as the second interlayer insulating film 5 between a partial side surface corresponding in height to the first side surface in a plurality of partial side surfaces of the second interlayer insulating film 5, and the reference plane of the semiconductor substrate 1a. The reference plane is used as a reference for height. In Embodiment 1, θᵢₙₛᵤ₂ denotes an angle formed between a tangential line of the partial side surface corresponding in height to the midpoint portion in the plurality of partial side surfaces, and the reference plane of the semiconductor substrate 1a. The partial side surface corresponding in height to the first side surface may be a partial side surface identical in height to the midpoint portion of the first side surface, or a partial side surface substantially identical in height to the midpoint portion of the first side surface.

θᵢₙₛᵤ₃ denotes an angle formed on the same side as the first interlayer insulating film 7 between a second side surface of the first interlayer insulating film 7 and the reference plane of the semiconductor substrate 1a. In Embodiment 1, θᵢₙₛᵤ₃ denotes an angle formed between a tangential line of a lower portion of the second side surface of the first interlayer insulating film 7 and the reference plane of the semiconductor substrate 1a.

θinsu4 denotes an angle formed on the same side as the second interlayer insulating film 5 between a partial side surface corresponding in height to the second side surface in a plurality of partial side surfaces of the second interlayer insulating film 5, and the reference plane of the semiconductor substrate 1a. In Embodiment 1, θᵢₙₛᵤ₄ denotes an angle formed between a tangential line of a partial side surface corresponding in height to a lower portion of the second side surface in the plurality of partial side surfaces, and the reference plane of the semiconductor substrate 1a. The partial side surface corresponding in height to the second side surface may be a partial side surface identical in height to the lower portion of the second side surface, or a partial side surface substantially identical in height to the lower portion of the second side surface.

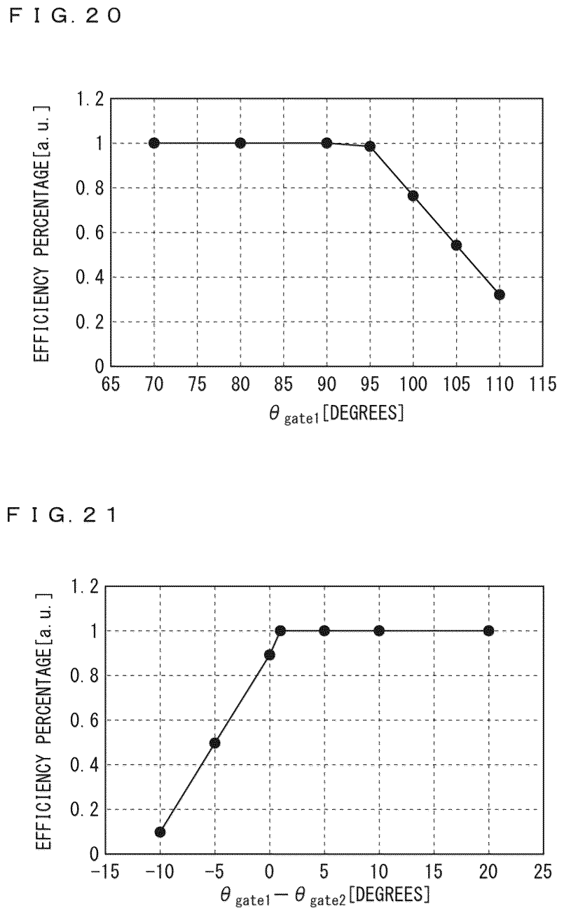

The semiconductor module in FIG. 18 was assembled, and a power cycling test of repeating a conduction state and a non-conduction state of the semiconductor device 1 was performed. FIG. 20 illustrates a relationship between θ_{gate1} and an efficiency percentage of the semiconductor module after the power cycling test has been performed 100 thousand times, and FIG. 21 illustrates a relationship between a difference between θ_{gate1} and θᵢₙₛᵤ₂ (θ_{gate1}−θᵢₙₛᵤ₂) and the efficiency percentage.

FIG. 20 illustrates the efficiency percentage of the semiconductor module after the power cycling test when the difference (θ_{gate1}−θᵢₙₛᵤ₂) is fixed to 20 degrees. The efficiency percentage decreases when θ_{gate1} is 100 degrees or more. Analysis on a faulty module whose θ_{gate1} is 100 degrees or more found that the second interlayer insulating film 5 closer to an upper end of the gate electrode 6 became cracked and the source electrode 3 and the gate electrode 6 were electrically shorted. This and the result of FIG. 20 show that a source-gate insulation failure can be suppressed when θ_{gate1} is 95 degrees or less.

FIG. 21 illustrates the efficiency percentage of the semiconductor module after the power cycling test when θ_{gate1} is fixed to 90 degrees. The efficiency percentage increases when θgate₁−θᵢₙₛᵤ₂>0, that is, when θᵢₙₛᵤ₂ is smaller than θ_{gate1}. This is probably because the external forces from the various materials such as the source electrode 3 and the mold resin 35 which surround the gate electrode 6 in the semiconductor device 1 are mitigated by a difference in angle between the second interlayer insulating film 5 and the gate electrode 6. The external forces occur due to the temperature difference between the heat generation time and the non-heat generation time in the termination region. Since θᵢₙₛᵤ₂ that is the second angle is smaller than θ_{gate1} that is the first angle in Embodiment 1, damage of the gate electrode 6 can be suppressed, and consequently, the reliability of the semiconductor device 1 can be enhanced.

Furthermore, θᵢₙₛᵤ₄ that is the fourth angle is larger than θᵢₙₛᵤ₃ that is the third angle as illustrated in FIG. 19 in Embodiment 1. As such, in a structure where the angle of the second interlayer insulating film 5 is made larger than the angle of the first interlayer insulating film 7, peeling of the source electrode 3 from the semiconductor substrate 1a through the barrier metal layer 4 by the external forces from the various materials such as the mold resin 35 can be suppressed. Thus, the reliability of the semiconductor device 1 can be enhanced.

In particular, the semiconductor device 1 including the semiconductor substrate 1a whose material is a wide bandgap semiconductor with higher dielectric breakdown field undergoes a significant increase in operating temperature. Thus, enhancing the reliability of the semiconductor device 1 as described above is effective. Examples of the wide bandgap semiconductor include silicon carbide (SiC), gallium nitride (GaN), and diamond.

While θ_{gate1}, θᵢₙₛᵤ₂, θᵢₙₛᵤ₃, and θᵢₙₛᵤ₄ are angles closer to the active region with respect to the first interlayer insulating film 7 in the example of FIG. 19, they may be, but not limited to, angles closer to the opposite region with respect to the first interlayer insulating film 7, or angles in a cross section except FIG. 19.

### Modification

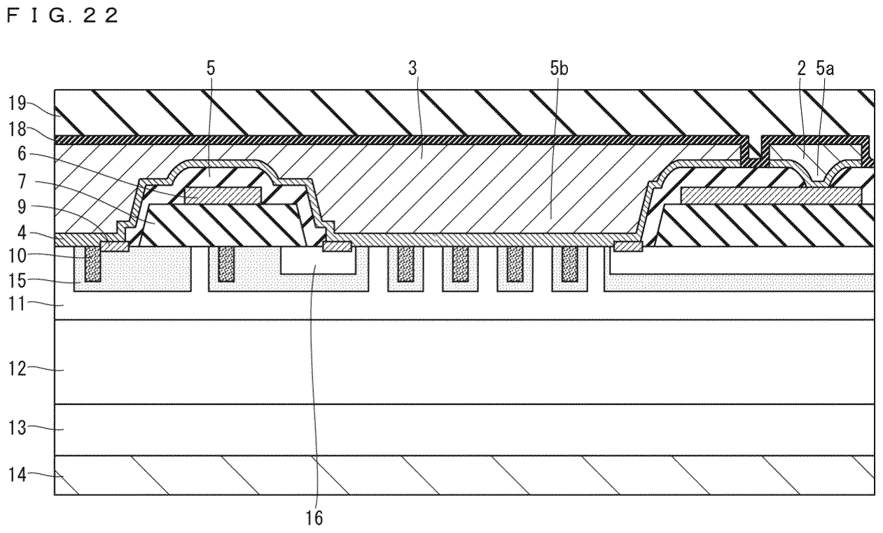

FIG. 22 is a schematic cross-sectional view illustrating a structure of the semiconductor device 1 according to a modification of Embodiment 1, and is a diagram corresponding to FIG. 3. As illustrated in FIG. 22, a protective film including a first protective film 18 covering the source electrode 3 and the gate wire 2, and a second protective film 19 covering the first protective film 18 may be provided. Example materials of the first protective film 18 preferably include an insulating material or a semi-insulating material, for example, a spin-on glass (SOG) or a silicon nitride film (SiₓN_{y}). Example materials of the second protective film 19 preferably include an insulating material or a semi-insulating material, for example, a polyimide film or a silicone resin.

### Embodiment 2

A top view of a structure of the semiconductor device 1 according to Embodiment 2 is similar to FIG. 1. The source electrode 3 is provided in the center of the upper portion of the semiconductor device 1, and the gate wire 2 is provided to surround the source electrode 3. The gate pad 17 is provided between the center and the end of the semiconductor device 1 to be electrically connected to the gate wire 2.

A top view between the active region and the termination region according to Embodiment 2 is similar to FIG. 2, and the SBD regions 20 and the MOS regions 22 are arranged in stripes.

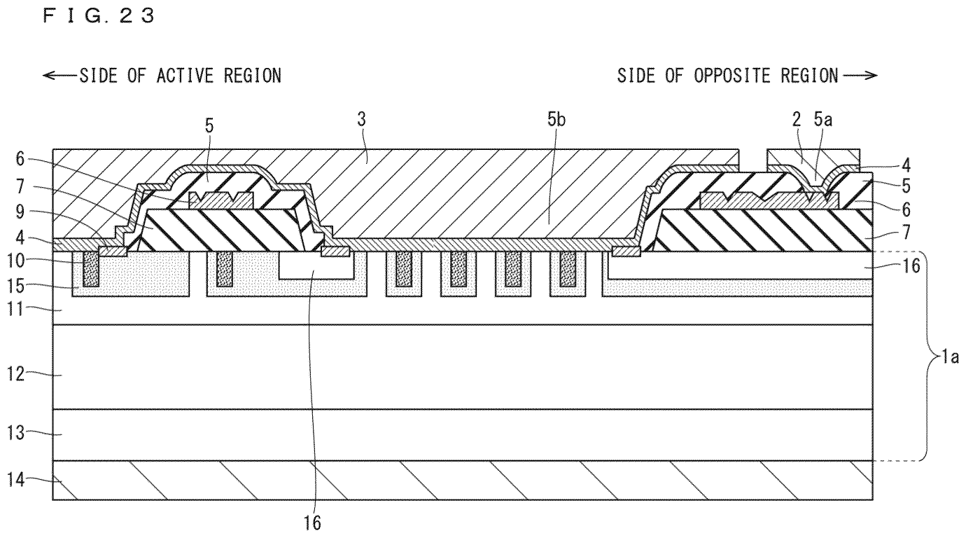

FIG. 23 is a cross-sectional schematic diagram illustrating a structure of the semiconductor device 1 according to Embodiment 2, and is specifically a cross-sectional schematic diagram illustrating a portion taken along the a-a′ line in FIG. 2. A surface of the gate electrode 6 which is connected to the second interlayer insulating film 5 is rougher than a surface of the gate electrode 6 which is connected to the first interlayer insulating film 7 in Embodiment 2. In the example of FIG. 23, while the surface of the gate electrode 6 which is connected to the first interlayer insulating film 7 is a lower surface, it may be a side surface, or the upper surface and the side surface.

### Manufacturing Method

A flowchart illustrating a method of manufacturing the semiconductor device 1 according to Embodiment 2 is similar to FIG. 4. While Embodiment 2 will also describe the SiC substrate 13 of n-type in detail, the SiC substrate may be of p-type. The steps up to a step for forming the gate oxide film in the active region as Step S7 for forming the gate oxide film in FIG. 4 are identical to those in Embodiment 1.

After Step S7 for forming the gate oxide film, the gate electrode 6 is formed on the upper surface of the first interlayer insulating film 7 using the photolithography technique and the dry or wet etching technique as Step S8 for forming the gate electrode as illustrated in FIG. 12. Example materials of the conductive film to be the gate electrode 6 may include polycrystalline Si or poly-Si to be deposited using chemical vapor deposition, etc., or tungsten or tungsten silicide (WSiₓ) when the semiconductor device 1 performs operations at higher speeds.

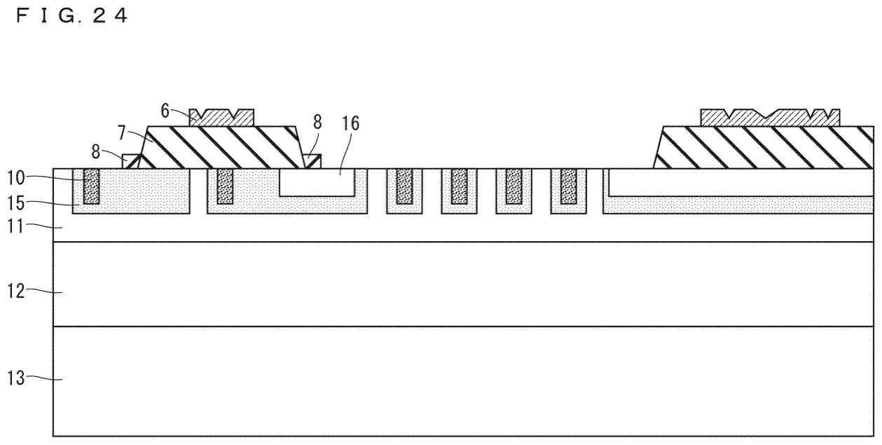

Next, as illustrated in FIG. 24, irregularities are provided on the front surface of the gate electrode 6 appropriately using the photolithography technique by dry etching using plasma containing, for example, fluorine and chlorine or by wet etching using a chemical solution containing hydrofluoric acid and nitric acid. This makes the surface of the gate electrode 6 which is connected to the second interlayer insulating film 5 rougher than the surface of the gate electrode 6 which is connected to the first interlayer insulating film 7 to be formed later.

After an amorphous Si film is deposited as a material of the gate electrode 6, the gate electrode 6 may be annealed at a temperature ranging from 500 to 700° C. to locally heat only the gate electrode 6 by flash lamp annealing. Such a step can form poly-Si from amorphous Si, and form, on the front surface of the gate electrode 6, the irregularities finer than those formed by the aforementioned etching method.

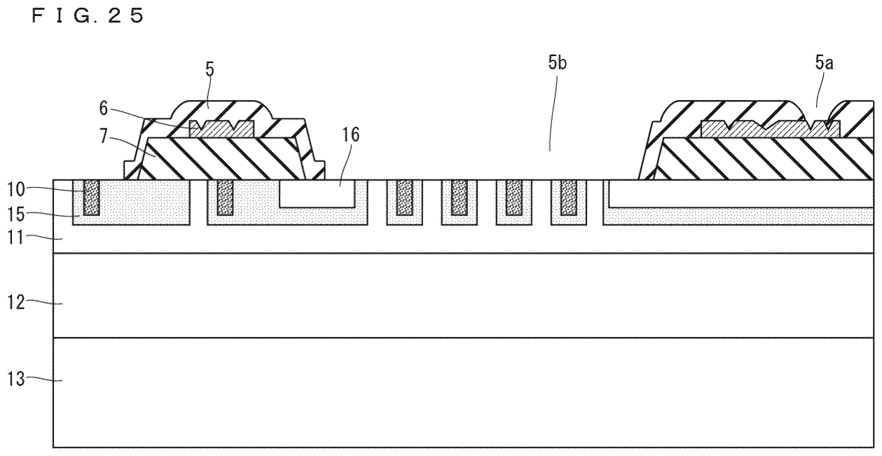

Then, in Step S9 for forming the second interlayer insulating film, an insulating film to be the second interlayer insulating film 5 is formed by CVD, and then, the insulating film is patterned using the photolithography technique and the dry or wet etching technique. This forms the second interlayer insulating film 5 that covers the gate electrode 6 and the first interlayer insulating film 7 and has the gate contact hole 5a and the contact hole 5b as illustrated in FIG. 25. The gate oxide film 8 is a part of the second interlayer insulating film 5 in Embodiment 1. Example materials of the second interlayer insulating film 5 include tetra ethoxy silane (TEOS) and borophosphosilicate glass (BPSG).

Next, in Step S10 for forming contact regions, the contact regions 9 are formed. Each of the contact regions 9 is, for example, a nickel silicide layer formed by depositing a metal film containing nickel (Ni) as a main component, on an opening in, for example, the photoresist and subjecting the metal film to a thermal process at a temperature ranging from 600 to 1100° C.

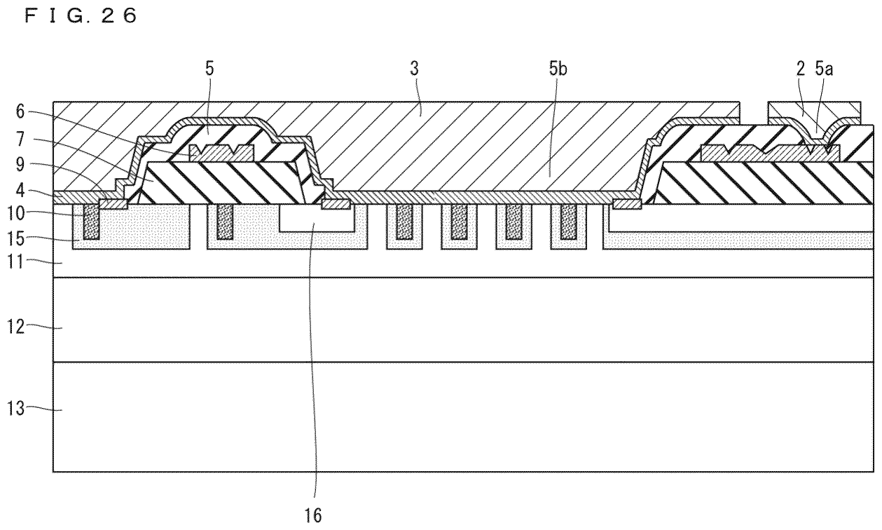

Next, in Step S11 for forming a source electrode, the barrier metal layer 4 made of titanium or a titanium compound such as or titanium nitride (TiN) is formed as illustrated in FIG. 26. Then, depositing, for example, one of aluminum and an aluminum alloy of aluminum and silicon, or nickel forms the gate wire 2 and the source electrode 3. Here, the fine irregularities on the front surface of the gate electrode 6 strengthen the connection between the gate electrode 6 and the second interlayer insulating film 5. Then, performing Step S12 for thinning the SiC substrate and Step S13 for forming the drain electrode similarly to Embodiment 1 completes the semiconductor device 1 illustrated in FIG. 23.

### Summary of Embodiment 2

In the semiconductor device 1 according to Embodiment 2 described above, the surface of the gate electrode 6 which is connected to the second interlayer insulating film 5 is rougher than the surface of the gate electrode 6 which is connected to the first interlayer insulating film 7. Such a structure can enlarge a contact area between the gate electrode 6 and the second interlayer insulating film 5. Thus, peeling of the gate electrode 6 and the second interlayer insulating film 5 by the external forces from the various materials such as the mold resin 35 that surrounds the gate electrode 6 in the semiconductor device 1 can be suppressed. The external forces occur due to the temperature difference between the heat generation time and the non-heat generation time in the termination region. Thus, the reliability of the semiconductor device 1 can be enhanced.

### Modification

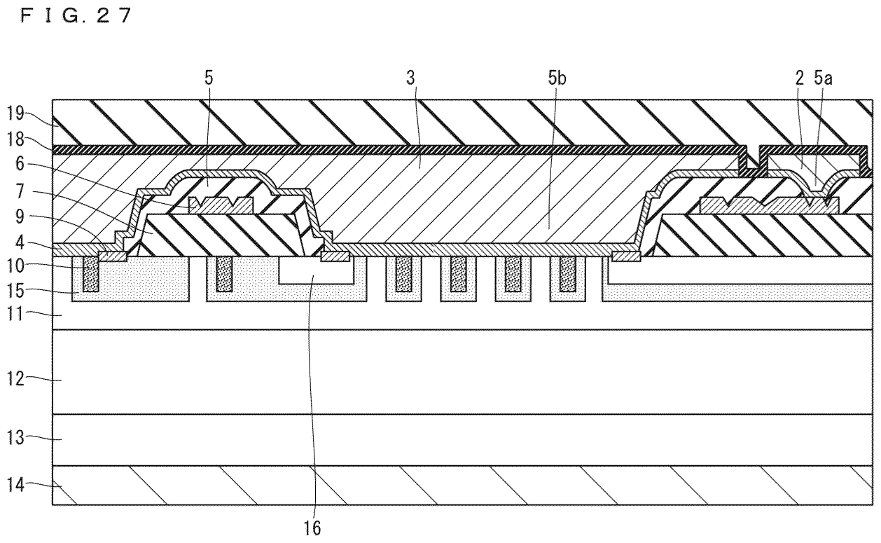

FIG. 27 is a schematic cross-sectional view illustrating a structure of the semiconductor device 1 according to a modification of Embodiment 2, and is a diagram corresponding to FIG. 3. As illustrated in FIG. 27, a protective film including the first protective film 18 covering the source electrode 3 and the gate wire 2, and the second protective film 19 covering the first protective film 18 may be provided also in Embodiment 2. Example materials of the first protective film 18 preferably include an insulating material or a semi-insulating material, for example, a spin-on glass (SOG) or a silicon nitride film (SiₓN_{y}). Example materials of the second protective film 19 preferably include an insulating material or a semi-insulating material, for example, a polyimide film or a silicone resin.

### Embodiment 3

A top view of a structure of a semiconductor device according to Embodiment 3 is similar to FIG. 1. The source electrode 3 is provided in the center of the upper portion of the semiconductor device 1, and the gate wire 2 is provided to surround the source electrode 3. The gate pad 17 is provided between the center and the end of the semiconductor device 1 to be electrically connected to the gate wire 2.

A top view between the active region and the termination region according to Embodiment 3 is similar to FIG. 2, and the SBD regions 20 and the MOS regions 22 are arranged in stripes. A cross-sectional schematic diagram illustrating a portion taken along the a-a′ line in FIG. 2 is similar to FIG. 3.

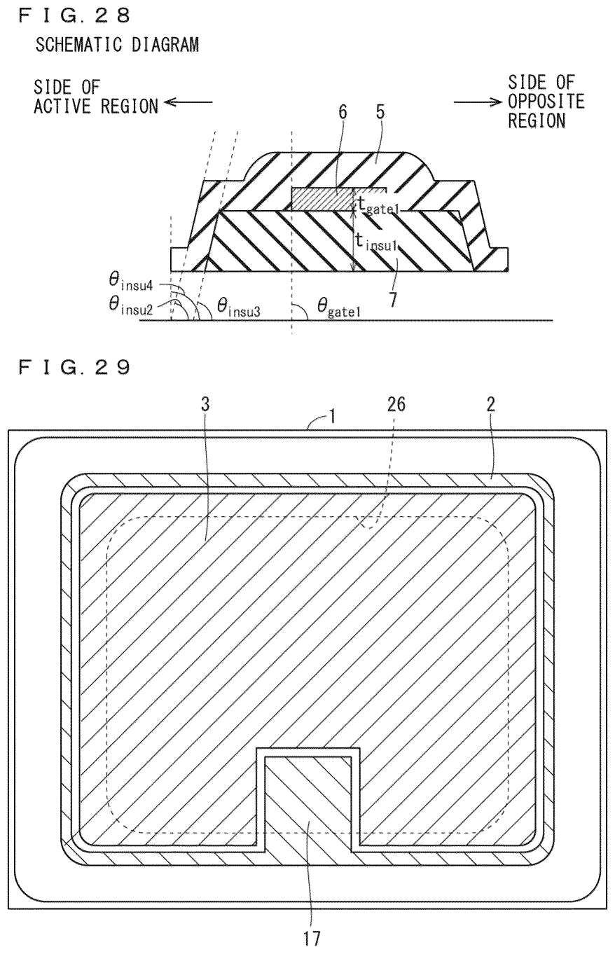

FIG. 28 is a schematic diagram illustrating a structure of the termination region in the semiconductor device 1 according to Embodiment 3. In addition to θ_{gate1} as the first angle, θᵢₙₛᵤ₂ as the second angle, θᵢₙₛᵤ₃ as the third angle, and θᵢₙₛᵤ₄ as the fourth angle, this schematic diagram indicates t_{gate1} as a thickness of the gate electrode 6 and tᵢₙₛᵤ₁ as a thickness of the first interlayer insulating film 7.

In Embodiment 3, tᵢₙₛᵤ₁ indicating the thickness of the first interlayer insulating film 7 is greater than t_{gate1} indicating the thickness of the gate electrode 6. This will be described later in detail.

### Manufacturing Method

The semiconductor device according to Embodiment 3 is manufactured by, for example, the flowchart in FIG. 4. Since Steps of Embodiment 3 are almost common to those of Embodiment 1, the detailed description is omitted herein. When an insulating film to be the first interlayer insulating film 7 is formed in CVD in Step S6 for forming the first interlayer insulating film in Embodiment 3, the first interlayer insulating film 7 with a thickness greater than that of the gate electrode 6 is formed in latter Step S8 for forming the gate electrode.

### Summary of Embodiment 3

Also in Embodiment 3, a current flows through the aforementioned diode in a freewheeling operation, in an inverter circuit including a power semiconductor device. The semiconductor device 1 including, in the termination region, the body diode (BD) regions and the Schottky barrier diode (SBD) regions for allowing a current to flow in a freewheeling operation generates heat in the termination region of the semiconductor device 1.

The thermal stresses caused by differences in thermal expansion coefficient between the various materials such as the gate electrode 6, the second interlayer insulating film 5 covering the gate electrode 6, and the source electrode 3 and the mold resin 35 which surround the second interlayer insulating film 5 occur in the gate electrode 6 and the second interlayer insulating film 5 covering the gate electrode 6 due to a temperature difference between the heat generation time and the non-heat generation time in the termination region. These thermal stresses add external forces to the gate electrode 6 through the second interlayer insulating film 5, so that the gate electrode 6 deteriorates and the semiconductor device 1 malfunctions.

In Embodiment 3, tᵢₙₛᵤ₁ indicating the thickness of the first interlayer insulating film 7 is greater than t_{gate1} indicating the thickness of the gate electrode 6. Since such a structure can share the external forces to be added to the gate electrode 6 not only by the gate electrode 6 but also by the first interlayer insulating film 7, the external forces to be added to the gate electrode 6 can be significantly mitigated. Thus, damage of the gate electrode 6 can be suppressed, and consequently, the reliability of the semiconductor device 1 can be enhanced.

### Embodiment 4

FIG. 29 is a top view illustrating a structure of a semiconductor device according to Embodiment 4. The source electrode 3 is provided in the center of the upper portion of the semiconductor device 1, and the gate wire 2 is provided to surround the source electrode 3. The gate pad 17 is provided between the center and the end of the semiconductor device 1 to be electrically connected to the gate wire 2. In Embodiment 4, a protective insulating film 26 covering a part of the source electrode 3 on the upper portion of the semiconductor device 1 and the gate wire 2 is provided.

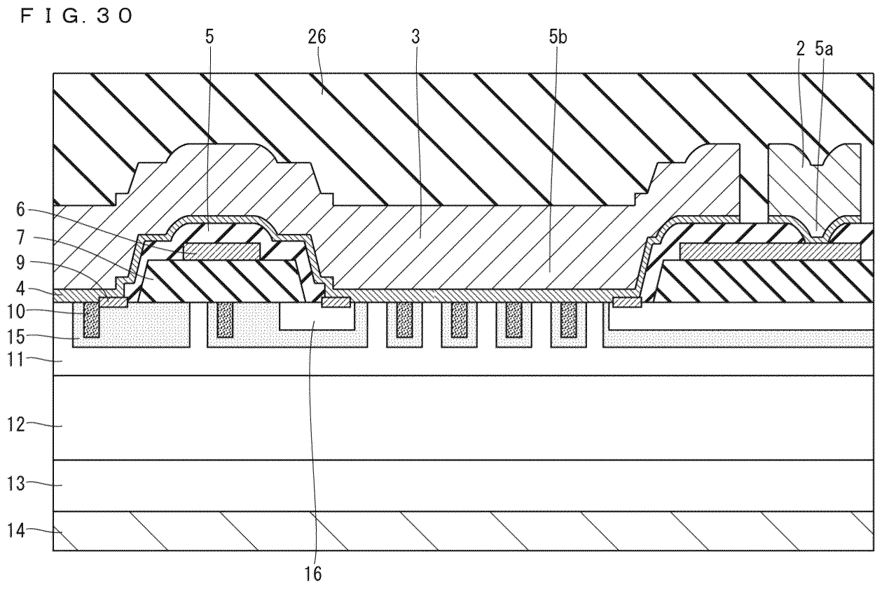

FIG. 30 is a cross-sectional schematic diagram illustrating a structure of the semiconductor device 1 according to Embodiment 4, and is specifically a cross-sectional schematic diagram illustrating a portion taken along the a-a′ line in FIG. 2. As will be described later, a portion of the protective insulating film 26 not above the gate electrode 6 but above the source electrode 3 is thicker than a portion of the protective insulating film 26 above both the gate electrode 6 and the source electrode 3 in Embodiment 4.

### Manufacturing Method

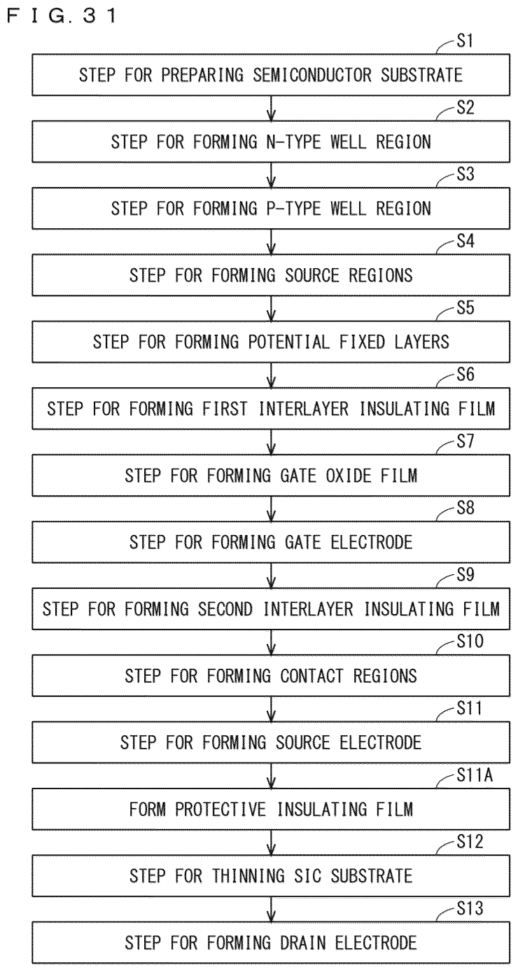

FIG. 31 is a flowchart illustrating a method of manufacturing the semiconductor device according to Embodiment 4. While Embodiment 4 will also describe the SiC substrate 13 of n-type in detail, the SiC substrate may be of p-type. The steps up to Step S10 for forming the contact regions in Embodiment 4, that is, up to the step for forming the contact regions 9 in FIG. 14 are identical to those of Embodiment 1.

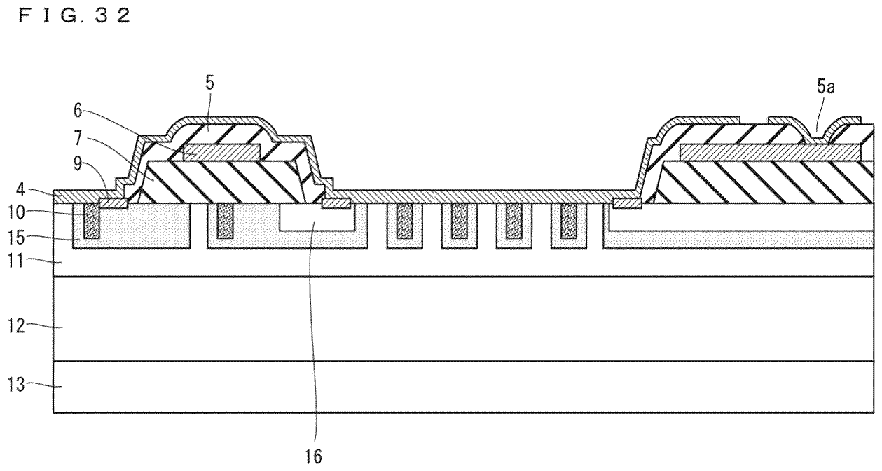

In Step S11 for forming the source electrode, the barrier metal layer 4 made of titanium or a titanium compound such as or titanium nitride (TiN) is formed as illustrated in FIG. 32. Low pressure chemical vapor deposition (LPCVD) involving thermal decomposition under reduced pressure for film deposition or a plasma-enhanced chemical vapor deposition (PECVD) technique facilitates covering the front surface of the semiconductor device which includes irregularities with the barrier metal layer 4.

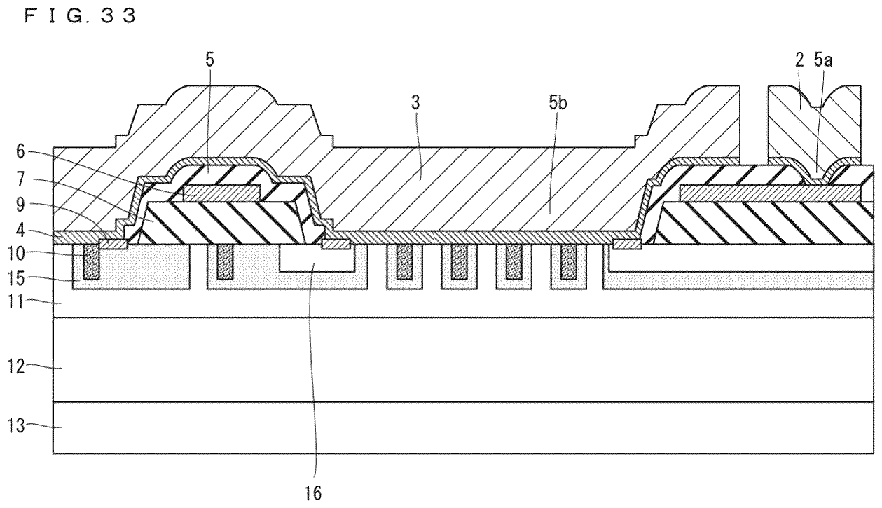

Then, the gate wire 2 and the source electrode 3 are formed by depositing one of aluminum and an aluminum alloy of aluminum and silicon with a physical vapor deposition (PVD) technique at high temperatures ranging from 250 to 500° C., preferably from 350 to 450° C. as illustrated in FIG. 33. For example, sputtering is used for the PVD technique. A combination of the CVD technique and a high-temperature PVD technique can facilitate forming a wire and an electrode even when a semiconductor device is downsized.

Then, in S11A for forming a protective insulating film, a polyimide film or a silicone resin is formed and patterned using the photolithography technology and the screen printing technology to form the protective insulating film 26 in FIG. 30. Then, performing Step S12 for thinning the SiC substrate and Step S13 for forming the drain electrode similarly to Embodiment 1 completes the semiconductor device 1 illustrated in FIG. 30.

### Summary of Embodiment 4

Also in Embodiment 4, a current flows through the aforementioned diode in a freewheeling operation in an inverter circuit including a power semiconductor device. The semiconductor device 1 including, in the termination region, the body diode (BD) regions and the Schottky barrier diode (SBD) regions for allowing a current to flow in a freewheeling operation generates heat in the termination region of the semiconductor device 1.

The thermal stresses caused by differences in thermal expansion coefficient between the various materials such as the gate electrode 6, the second interlayer insulating film 5 covering the gate electrode 6, and the source electrode 3 and the mold resin 35 which surround the second interlayer insulating film 5 occur in the gate electrode 6 and the second interlayer insulating film 5 covering the gate electrode 6 due to a temperature difference between the heat generation time and the non-heat generation time in the termination region. These thermal stresses add external forces to the gate electrode 6 through the second interlayer insulating film 5, so that the gate electrode 6 deteriorates and the semiconductor device 1 malfunctions.

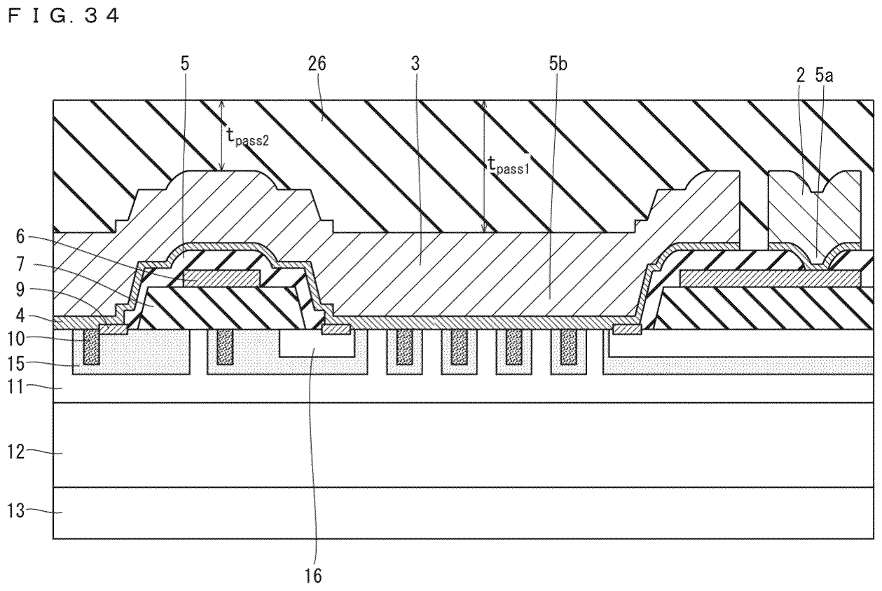

As illustrated in FIG. 34, a thickness tₚₐₛₛ₁ of a portion of the protective insulating film 26 not above the gate electrode 6 but above the source electrode 3 is greater than a thickness tₚₐₛₛ₂ of a portion of the protective insulating film 26 above both the gate electrode 6 and the source electrode 3 in Embodiment 4. Since such a structure can share the external forces to be added to the gate electrode 6 not only by the gate electrode 6 but also by deformation of the protective insulating film 26, the external forces to be added to the gate electrode 6 can be significantly mitigated. Thus, damage of the gate electrode 6 can be suppressed, and consequently, the reliability of the semiconductor device 1 can be enhanced.

### Embodiment 5

Embodiment 5 will describe a power conversion device to which the semiconductor devices according to Embodiments 1 to 4 are applied. The semiconductor device 1 is, for example, a silicon carbide semiconductor device. Although the present disclosure is not limited to specific power conversion devices, application of the power conversion device according to Embodiment 5 to a three-phase inverter will be hereinafter described in detail.

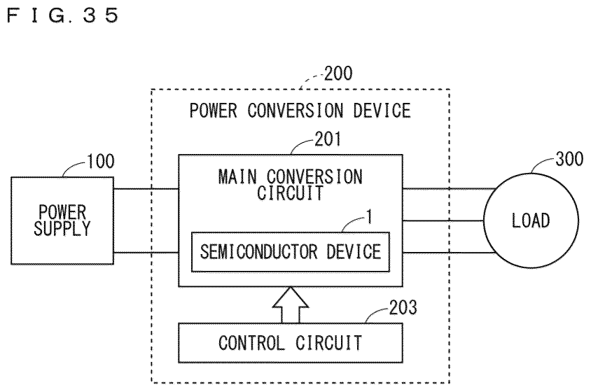

FIG. 35 is a block diagram schematically illustrating a configuration of a power conversion system to which a power conversion device 200 according to Embodiment 5 is applied. This power conversion system includes a power supply 100, the power conversion device 200, and a load 300.

The power supply 100, which is a DC power supply, supplies a DC power to the power conversion device 200. The power supply 100 may include various components such as a DC system, a solar battery, and a rechargeable battery, a rectifying circuit connected to an AC system, or an AC/DC converter. The power supply 100 may include a DC/DC converter which converts the DC power output from a DC system into a predefined power.

The power conversion device 200 is a three-phase inverter connected between the power supply 100 and the load 300. The power conversion device 200 converts the DC power supplied from the power supply 100 into the AC power to supply the AC power to the load 300. The power conversion device 200 includes a main conversion circuit 201 and a control circuit 203. The main conversion circuit 201 converts the input DC power into the AC power to output the AC power. The control circuit 203 outputs, to the main conversion circuit 201, a control signal for controlling the main conversion circuit 201.

The load 300 is a three-phase electrical motor driven by the AC power supplied from the power conversion device 200. The load 300 is not limited to specific use but is an electrical motor mounted on various types of electrical devices. Thus, the load 300 is used as an electrical motor for, for example, a hybrid car, an electrical car, a rail vehicle, an elevator, or air-conditioning equipment.

The power conversion device 200 will be described in detail hereinafter. The main conversion circuit 201 includes the switching devices and freewheeling diodes (not illustrated). Switching of the switching devices allows the main conversion circuit 201 to convert the DC power supplied from the power supply 100 into the AC power and supply the AC power to the load 300. The specific circuit configuration of the main conversion circuit 201 is of various types. The main conversion circuit 201 according to Embodiment 5 is a three-phase full-bridge circuit having two levels, and includes six switching devices and six freewheeling diodes anti-parallel connected to the respective switching devices. The semiconductor device 1 according to one of Embodiments 1 to 4 and its modifications is applied as at least one of the switching devices and the freewheeling diodes of the main conversion circuit 201. The six switching devices form pairs of upper and lower arms in each pair of which the two switching devices are serially connected to each other. The pairs of upper and lower arms form the respective phases (U-phase, V-phase, and W-phase) of the full-bridge circuit. Output terminals of the respective pairs of upper and lower arms, i.e., three output terminals of the main conversion circuit 201 are connected to the load 300.

Furthermore, the main conversion circuit 201 includes a drive circuit (not illustrated) that drives each of the switching devices. The drive circuit generates driving signals for driving the switching devices of the main conversion circuit 201, and provides the driving signals to control electrodes of the switching devices of the main conversion circuit 201. Specifically, the drive circuit outputs the driving signal for switching each of the switching devices to an ON state and the driving signal for switching the switching device to an OFF state, to a control electrode of the switching device in accordance with the control signal from the control circuit 203 to be described later. When the switching device is kept in the ON state, the driving signal is a voltage signal (ON signal) higher than or equal to a threshold voltage of the switching device. When the switching device is kept in the OFF state, the driving signal is a voltage signal (OFF signal) lower than the threshold voltage of the switching device.

The control circuit 203 controls the switching devices of the main conversion circuit 201 to supply a desired power to the load 300. Specifically, the control circuit 203 calculates a time (ON time) when each of the switching devices of the main conversion circuit 201 needs to enter the ON state, based on the power which needs to be supplied to the load 300. For example, the control circuit 203 can control the main conversion circuit 201 by pulse width modulation (PWM) control for modulating the ON time of the switching devices in accordance with the voltage which needs to be output. Then, the control circuit 203 outputs a control instruction (a control signal) to the drive circuit included in the main conversion circuit 201 so that the drive circuit outputs the ON signal to the switching device which needs to enter the ON state and outputs the OFF signal to the switching device which needs to enter the OFF state at each time. The drive circuit outputs the ON signal or the OFF signal as the driving signal to the control electrode of each of the switching devices in accordance with this control signal.

A method of manufacturing the power conversion device 200 includes the following steps. The semiconductor device 1 is manufactured by the manufacturing method described in Embodiments or its modifications above. The main conversion circuit 201 including the semiconductor device 1 is formed. Furthermore, the control circuit 203 is formed. This produces the power conversion device 200. When the main conversion circuit 201 is formed, the drain electrode 14 of the semiconductor device 1 is bonded to a mounting substrate, and the source electrode 3 of the semiconductor device 1 is bonded to the mounting substrate through a wire.

In the power conversion device according to Embodiment 5, the aforementioned semiconductor device 1 is used as at least one of the semiconductor devices included in the main conversion circuit 201. This can suppress an unexpected detrimental effect on the assembly of the semiconductor device 1, and can suppress malfunctions of the semiconductor device 1 which are caused by stresses from peripheral components in switching operations. This enhances the reliability of the main conversion circuit 201. Thus, the reliability of the power conversion device 200 can be enhanced.

While Embodiment 5 describes the example of applying the present disclosure to the three-phase inverter having the two levels, the present disclosure is not limited thereto, but is applicable to various power conversion devices. While the power conversion device according to Embodiment 5 is the power conversion device having the two levels, the power conversion device may be a power conversion device having multiple levels, for example, three levels. Furthermore, the present disclosure may be applied to a single-phase inverter when the power is supplied to a single-phase load. Furthermore, the present disclosure is also applicable to a DC/DC converter or an AC/DC converter when the power is supplied to, for example, a DC load.

The load of the power conversion device to which the present disclosure is applied is not limited to the electrical motor as described above. The power conversion device can also be used as a power-supply device of, for example, an electrical discharge machine, a laser beam machine, an induction heat cooking device, or a non-contact power feeding system, and can be further used as a power conditioner of, for example, a solar power system or an electricity storage system.

Embodiments and its modifications can be freely combined, or appropriately modified and omitted.

The description is in all aspects illustrative, and is not restrictive. Therefore, numerous modifications that have not yet been exemplified will be devised.

A summary of various aspects of the present disclosure will be hereinafter described as Appendixes.

### Appendix 1

A semiconductor device, comprising:
   a semiconductor substrate;
   a first insulating film provided on a reference plane of the semiconductor substrate;
   a first electrode provided on the first insulating film;
   a second insulating film covering the reference plane, the first insulating film, and the first electrode; and
   a second electrode covering the reference plane and the second insulating film,
   wherein a side surface of the second insulating film includes a plurality of partial side surfaces forming different angles with the reference plane, and
   a second angle formed between the reference plane and a partial side surface corresponding in height to a first side surface of the first electrode is smaller than a first angle formed between the first side surface and the reference plane, the partial side surface being included in the plurality of partial side surfaces.

### Appendix 2

The semiconductor device according to appendix 1, wherein the first angle is 95 degrees or less.

### Appendix 3

The semiconductor device according to appendix 1 or 2, wherein a fourth angle formed between the reference plane and a partial side surface corresponding in height to a second side surface of the first insulating film is larger than a third angle formed between the second side surface and the reference plane, the partial side surface being included in the plurality of partial side surfaces.

### Appendix 4

The semiconductor device according to any one of appendixes 1 to 3,
wherein a surface of the first electrode which is connected to the second insulating film is rougher than a surface of the first electrode which is connected to the first insulating film.

### Appendix 5

The semiconductor device according to any one of appendixes 1 to 4, wherein the first insulating film is thicker than the first electrode.

### Appendix 6

The semiconductor device according to any one of appendixes 1 to 5, further comprising a protective insulating film covering the first electrode and the second electrode, wherein a portion of the protective insulating film not above the first electrode but above the second electrode is thicker than a portion of the protective insulating film above both the first electrode and the second electrode.

### Appendix 7

The semiconductor device according to any one of appendixes 1 to 6, wherein the first electrode is electrically connected to an electrode provided on a metal-oxide semiconductor region of the semiconductor device.

### Appendix 8

A power conversion device, comprising:
a main conversion circuit including the semiconductor device according to any one of appendixes 1 to 7, the main conversion circuit converting an input power to output a resulting power; and
a control circuit outputting, to the main conversion circuit, a control signal for controlling the main conversion circuit.

### EXPLANATION OF REFERENCE SIGNS

1 semiconductor device, 1a semiconductor substrate, 3 source electrode, 5 second interlayer insulating film, 6 gate electrode, 7 first interlayer insulating film, 201 main conversion circuit, 203 control circuit.

1. A semiconductor device, comprising:
a semiconductor substrate;
a first insulating film provided on a reference plane of the semiconductor substrate;
a first electrode provided on the first insulating film;
a second insulating film covering the reference plane, the first insulating film, and the first electrode; and
a second electrode covering the reference plane and the second insulating film,
wherein a side surface of the second insulating film includes a plurality of partial side surfaces forming different angles with the reference plane, and
a second angle formed between the reference plane and a partial side surface corresponding in height to a first side surface of the first electrode is smaller than a first angle formed between the first side surface and the reference plane, and the first insulating film is thicker than the first electrode, the partial side surface being included in the plurality of partial side surfaces.

2. The semiconductor device according to claim 1,
wherein the first angle is 95 degrees or less.

3. The semiconductor device according to claim 1,
wherein a fourth angle formed between the reference plane and a partial side surface corresponding in height to a second side surface of the first insulating film is larger than a third angle formed between the second side surface and the reference plane, the partial side surface being included in the plurality of partial side surfaces.

4. The semiconductor device according to claim 1,
wherein a surface of the first electrode which is connected to the second insulating film is rougher than a surface of the first electrode which is connected to the first insulating film.

5. (canceled)

6. The semiconductor device according to claim 1, further comprising
a protective insulating film covering the first electrode and the second electrode,
wherein a portion of the protective insulating film not above the first electrode but above the second electrode is thicker than a portion of the protective insulating film above both the first electrode and the second electrode.

7. The semiconductor device according to claim 1,
wherein the first electrode is electrically connected to an electrode provided on a metal-oxide semiconductor region of the semiconductor device.

8. A power conversion device, comprising:
a main conversion circuit including the semiconductor device according to claim 1, the main conversion circuit converting an input power to output a resulting power; and
a control circuit outputting, to the main conversion circuit, a control signal for controlling the main conversion circuit.
